(19) United States
(12) Patent Application Publication
(10) Pub. No.: US 2011/0097517 A1
(43) Pub. Date: Apr. 28, 2011

(54) DYNAMIC VERTICAL MICROWAVE DEPOSITION OF DIELECTRIC LAYERS

(75) Inventors: Michael W. Stowell, Loveland, CO (US); Klaus Michael, Gelnhausen (DE)

(73) Assignee: Applied Materials, Inc., Santa Clara, CA (US)

(21) Appl. No.: 12/833,571

(22) Filed: Jul. 9, 2010

Related U.S. Application Data
(63) Continuation-in-part of application No. PCT/US2008/052383, filed on Jan. 30, 2008.
(60) Provisional application No. 61/224,224, filed on Jul. 9, 2009.
(60) Provisional application No. 61/224,234, filed on Jul. 9, 2009.
(60) Provisional application No. 61/224,371, filed on Jul. 9, 2009.
(60) Provisional application No. 61/224,245, filed on Jul. 9, 2009.

(51) Int. Cl. C23C 16/511; C23C 16/455; C23C 16/458; C23C 16/46

(52) U.S. Cl. 427/575; 118/723 MW; 118/719

(57) ABSTRACT

Systems and methods for depositing protection and dielectric layers using a vertical microwave deposition processes are provided. In some embodiments, a microwave antenna is vertically attached to a sidewall of a processing chamber. A substrate can be introduced of placed within the processing chamber in a substantially vertical configuration or in a configuration where the substrate is parallel to a sidewall of the processing chamber. A plasma can be formed with the microwave antenna and various precursor materials, such as precursors that include magnesium or silicon. A processing chamber with multiple sub-chambers is also provided according to some embodiments of the invention. Various sub-chambers can have vertical microwave plasma line sources. Other sub-chambers can providing heating and other processes. At least one substrate supporting member can be used to move the substrate vertically from one sub-chamber to another.

### CROSS-REFERENCES

This patent application is a non-provisional of and claims the benefit of U.S. Provisional Patent Application No. 61/224,224, entitled “High Efficiency Low Energy Microwave Ion/Electron Source,” filed Jul. 9, 2009, the entire disclosures of which are incorporated herein by reference for all purposes.

This patent application is a non-provisional of and claims the benefit of U.S. Provisional Patent Application No. 61/224,234, entitled “Curved Surface Wave Fired Plasma Line for Coating of 3 Dimensional Substrates,” filed Jul. 9, 2009, the entire disclosures of which are incorporated herein by reference for all purposes.

This patent application is a non-provisional of and claims the benefit of U.S. Provisional Patent Application No. 61/224,371, entitled “Simultaneous Vertical Deposition of Plasma Displays Layers,” filed Jul. 9, 2009, the entire disclosures of which are incorporated herein by reference for all purposes.

This patent application is a non-provisional of and claims the benefit of U.S. Provisional Patent Application No. 61/224,245, entitled “Microwave Linear Deposition of Plasma Display Protection Layers,” filed Jul. 9, 2009, the entire disclosures of which are incorporated herein by reference for all purposes.

This patent application is a continuation-in-part application of International Application No. PCT/US2008/052383, entitled “System and Method for Microwave Plasma Species Source,” filed 30 Jan. 2008, the entire disclosures of which are incorporated herein by reference for all purposes.

### BACKGROUND OF THE INVENTION

Plasma displays commonly include a protection layer (e.g., MgO) on dielectric layers (e.g., SiO, SiN, PbO₂). Generally, a plasma display panel (PDP) is a display device which displays characters or graphics. In operation, a predetermined voltage is applied across two electrodes to generate plasma discharge within a discharge space of the plasma display panel. The resulting plasma discharge can generate ultraviolet light that excites a phosphor film to generate visible light of a predetermined pattern. The visible light displays desired images.

Plasma display panels are generally classified as an AC type, a DC type, or a hybrid type. FIG. 1 shows an exploded perspective view of a discharge cell of a common AC type plasma display panel. As shown in FIG. 1, a plasma display panel 100 includes a front (top) substrate 102a and a rear (bottom) substrate 102b, a plurality of address electrodes 104 formed on the bottom substrate 102b, a lower dielectric layer 106 formed on the address electrodes 104, and a plurality of barrier ribs 108 formed on the lower dielectric layer 106 to maintain a discharge distance while preventing inter-cell cross talk. The plasma display panel 100 also includes a phosphor layer 116 formed on the plurality of barrier ribs 108 and the lower dielectric layer 106, a protection layer 110 for protecting an upper dielectric layer 112. The protection layer 110 is coupled to the barrier rib 108. Under the top substrate 102a are discharge sustain electrodes 118. The plasma display panel also includes a plurality of bus bars or silver 114 on the edge of the discharge sustain electrodes 118 and the upper dielectric layer 112.

The discharge sustain electrodes 118 are spaced apart from the address electrodes 104 by a predetermined distance. The upper dielectric layer 112 and the protection layer 110 sequentially cover the discharge sustain electrodes 118 and silver 114. The protection layer 110 is typically formed from MgO, which is optically transparent in wavelength ranging from 300 nm to 7 μm, including visible lights ranging from 380 nm to 850 nm. It is known in the art that such a MgO-based layer can protect the dielectric layer while maintaining excellent electron emission capacity. The MgO protective layer 110 usually has a thickness of 1-2 μm, and protects the dielectric layer 112 from ion bombardment, and emits secondary electrons to lower the discharge voltage.

As the MgO protective layer contacts the discharge gas, formation conditions of the MgO layer may greatly influence the discharge characteristics and the performance of the MgO protective layer. The MgO protective layer may be formed using various techniques, such as sputtering, electron beam deposition, chemical vapor deposition (CVD), ion beam plating deposition, and sol-gel.

One of the most common techniques is the electron beam deposition technique. In this technique, electron beams are accelerated by electric voltage of 12 kV to 18 kV to collide against a MgO target material to heat and vaporize the MgO, and then a solid MgO protective layer is formed as the material condenses onto the substrate. The deposition chamber may be evacuated to a pressure of 10⁻⁴ ton. The process, however, fails to provide film thickness homogeneity as that produced in sputtering deposited films. Therefore, the electron beam technology suffers from severe outgassing and requires long annealing cycle times.

Sputtering is a thin film deposition process where atoms are ejected from a solid target material due to bombardment of the target by energetic ions and are deposited on a substrate. Compared to the electron beam deposition technique, sputtering techniques make the protective layer denser and provides improved crystal alignment, but produces high defect densities and can then yield poor response times.

The sol-gel technique is a wet-chemical technique to form metal oxides. The process starts from a chemical solution. Removal of the remaining solvent requires a drying process, which is typically accompanied by a significant amount of shrinkage, stress and densification.

The ion beam assisted deposition (IBAD) may be used in conjunction with the other deposition techniques, such as electron beam, sputtering, sol-gel etc. The IBAD uses ion beams to bombard the films of internal stress that results from thermal expansion mismatch between the substrate and the films. The IBAD can also be used to modify properties of the films, such as density, grain size, and structure etc.

Conventional thermal CVD processes supply reactive gases to the substrate surface where heat-induced chemical reactions take place to produce a desired film. Plasma-enhanced CVD (“PECVD”) techniques promote excitation and/or dissociation of the reactant gases by the application of radio-frequency (“RF”) energy to a reaction zone near the substrate surface, thereby creating a plasma. The high reactivity of the species in the plasma reduces the energy required for a chemical reaction to take place on the substrate surface, and thus lowers the temperature required for such CVD processes when compared with conventional thermal CVD processes. These advantages may be further exploited by high-density-plasma (“HDP”) CVD techniques, in which a dense plasma is formed at low vacuum pressures so that the plasma species are even more reactive. While each of these techniques falls broadly under the umbrella of “CVD techniques,” each of them has characteristic properties that make them more or less suitable for certain specific applications.

Plasma displays commonly include a protection layer (e.g., MgO) on dielectric layers (e.g., SiO, SiN, PbO₂). Generally, a plasma display panel (PDP) is a display device which displays characters or graphics. In operation, a predetermined voltage is applied across two electrodes to generate plasma discharge within a discharge space of the plasma display panel. The resulting plasma discharge can generate ultraviolet light that excites a phosphor film to generate visible light of a predetermined pattern. The visible light displays desired images.

Typically, plasma display dielectric and protection layers are deposited in a horizontal configuration due to utilization of common sources. The protective layer MgO is often deposited by the electron beam deposition technique, while the dielectric layer is deposited by using a planar PECVD technique. Current industrial methods for manufacturing of plasma displays use two separate sources for depositing MgO and dielectric layers. Therefore, the process for depositing the MgO layer is incompatible with the process for depositing the dielectric layer. The deposition of the dual layers, i.e. the dielectric layer and the protective MgO layer, needs to be performed in two different machines and each of the machines has its own source and processing conditions.

This traditional deposition process has some drawbacks. For example, it requires utilization of relatively large consumption of electrical power and floor space. The traditional deposition process also yields large quantities of toxic wastes and produces films of high dielectric constant. Such high dielectric constant may result in severe loss of power efficiency in products such as plasma displays.

In the plasma display industry, chemical techniques have been developed to decrease a softening temperature of dielectric materials to below a softening temperature of the substrate. The chemical techniques introduce chemicals, such as polymer binders. As a result, the dielectric constant of an actual formed dielectric layer would have a typical value of about 15, which is significantly higher than a theoretical value of 4.0 for SiO₂. Therefore, in order to maintain the required breakdown voltage and capacitance to a manageable amount, a film thickness needs to be increased to its present value, i.e. 25-35 μm for the top dielectric layer, and 10 μm for the bottom dielectric layer.

### BRIEF SUMMARY OF THE INVENTION

According to one embodiment of the invention, a CVD system comprises a processing chamber having a first, second, third and fourth sub-chambers. The first and second sub-chambers have a first and a second microwave plasma line sources vertically coupled to a first sidewall of the processing chamber, and the third and fourth sub-chambers have a third and a fourth microwave plasma line sources vertically coupled to a second sidewall of the processing chamber. The CVD system can also include at least one substrate supporting member for supporting a substrate in a vertical configuration within the processing chamber. The substrate supporting member can be positioned between the first sidewall and the second sidewall. The substrate supporting member can also be configured to rotate the substrate. The system can also include a plurality of precursor lines coupled into the processing chamber.

According to another embodiment of the present invention, a method for depositing multiple layers is provided. The method includes loading a substrate into a processing chamber that can include first and second sub-chambers. Each of the first and second sub-chambers can have a respective microwave plasma line source vertically coupled to one of a first or a second sidewall of the processing chamber. The substrate can be supported by at least one substrate supporting member in a vertical configuration within the processing chamber. The substrate supporting member is positioned between the first sidewall and the second sidewall. The method also includes introducing a first group of precursors into the first sub-chamber, depositing a first layer on the substrate in the first sub-chamber with the first group of precursors, and removing the remnants of the first group of precursors from the processing chamber. The method further includes transferring the substrate from the first sub-chamber to the second sub-chamber within the processing chamber, introducing a second group of precursors into the processing chamber and depositing a second layer over the first layer in the second sub-chamber with the second group of precursors.

Additional embodiments and features are set forth in part in the description that follows, and in part will become apparent to those skilled in the art upon examination of the specification or may be learned by the practice of the invention. A further understanding of the nature and advantages of the present invention may be realized by reference to the remaining portions of the specification and drawings.

Some embodiments of the present invention include methods for depositing magnesium oxide on a substrate. In some embodiments, a microwave antenna is provided within a processing chamber, where the microwave antenna is vertically attached to a sidewall of the processing chamber. The method can also include loading a substrate into the processing chamber by disposing the substrate over a substrate supporting member in the processing chamber, where the substrate supporting member is positioned vertically such that the substrate is substantially parallel to the sidewall. The method can further include generating microwaves with the microwave antenna and modulating a power of the generated microwaves. Moreover, the method can include flowing a magnesium containing precursor and an oxygen containing precursor into the processing chamber and forming a plasma inside the processing chamber from the magnesium containing precursor and the oxygen containing precursor with the generated microwaves. Furthermore, the method can include depositing a magnesium oxide layer on the substrate with the plasma.

According to some embodiments of the present invention, the method can further include flowing silicon containing precursors and/or oxygen containing precursors into the processing chamber and/or forming a plasma inside the processing chamber from the silicon containing precursor and/or oxygen containing precursor. Moreover, the method can include depositing a silicon oxide layer on the substrate and/or cleaning the remaining silicon containing precursors prior to depositing the magnesium oxide.

According to another embodiment of the present invention, a microwave PECVD system can include a processing chamber with a microwave coaxial line source inside the chamber for radiating microwaves. The microwave coaxial line source can be vertically attached to a portion of the sidewall of the processing chamber. The system can further include a substrate supporting member disposed within the processing chamber for holding a substrate, where the substrate supporting member is positioned vertically such that the substrate is substantially parallel to the sidewall. Furthermore, the system includes a gas supply system for flowing gases into the processing chamber.

The system and method have many benefits over conventional systems. One of the benefits is that the microwave PECVD system may yield high density MgO film with low number of defects. The vertical configuration of the microwave coaxial line source and the substrate can allow deposition of MgO film after depositing dielectric layers in the same deposition system. This could significantly reduce the floor space and manufacturing cost for fabricating plasma display.

Additional embodiments and features are set forth in part in the description that follows, and in part will become apparent to those skilled in the art upon examination of the specification or may be learned by the practice of the invention. A further understanding of the nature and advantages of the present invention may be realized by reference to the remaining portions of the specification and drawings.

### BRIEF DESCRIPTION OF THE DRAWINGS

FIG. 1 illustrates a basic film structure of a typical AC coplanar plasma display panel.

FIG. 2 illustrates a chart showing light efficiency vs. capacitance and voltage.

FIG. 3 illustrates a microwave coaxial plasma line source according to some embodiments of the invention.

FIG. 4 illustrates a microwave coaxial twin line source according to some embodiments of the invention.

FIG. 5 provides a simplified schematic of a planar plasma source consisting of 4 coaxial microwave linear sources according to some embodiments of the invention.

FIG. 6 illustrates a vertical arrangement of microwave assisted PECVD for depositing MgO according to some embodiments of the invention.

FIG. 7 illustrates a horizontal arrangement of microwave assisted PECVD for depositing MgO according to some embodiments of the invention.

FIG. 8 is a flow chart illustrating steps for depositing a MgO layer according to some embodiments of the invention.

FIG. 9 is a photograph of a vertical coaxial line source according to some embodiments of the invention.

FIG. 10 illustrates one embodiment of a top view of a vertical in-line machine for deposition of plasma display dielectric and protection layers.

FIG. 11 illustrates a side view of a door with plasma source attached according to some embodiments of the invention.

FIG. 12 illustrates a flow diagram for steps in depositing a dual layer in a single deposition system according to some embodiments of the invention.

### DETAILED DESCRIPTION OF THE INVENTION

Embodiments of the invention provide deposition techniques using a single integrated machine with a single type of microwave coaxial plasma line source. The source and the substrate are configured in vertical arrangements. The substrate can be transferred from one location to another location within the chamber in a dynamic fashion. The substrate can also be rotated, for example, 180 degrees about the vertical, to expose to different microwave coaxial line sources or other treatment. The single integrated machine can provide a particle free deposition with high throughput and can also remove a venting cycle that is required to provide a layer stack of high quality for plasma display performance.

Microwave PECVD

A microwave frequency source can be one technique for increasing plasma density. At low frequencies electromagnetic waves do not propagate in a plasma, but are instead reflected. However, at high frequencies such as typical microwave frequencies, electromagnetic waves effectively allow direct heating of plasma electrons. As the microwave inputs energy into the plasma, collisions can occur to ionize the plasma so that higher plasma density can be achieved. In some embodiments, horns can be used to inject microwave, or a small stub antenna can be placed in the vacuum chamber adjacent to a sputtering cathode for inputting the microwave into the chamber. However, these techniques do not provide a homogeneous assist to enhance plasma generation. And these may not provide enough plasma density to sustain its own discharge without the assistance of the sputtering cathode. Additionally, scale up of such systems for large area deposition is limited to a length on the order of 1 meter or less due to non-linearity.

Microwave plasma has been developed to achieve higher plasma densities (e.g., 10¹² ions/cm³) and higher deposition rates, as a result of improved power coupling and absorption at 2.45 GHz when compared to a typical radio frequency (RF) coupled plasma source at 13.56 MHz. One drawback of the RF plasma is that a large portion of the input power is dropped across the plasma sheath (dark space). By using microwave plasma, a narrow plasma sheath is formed and more power can be absorbed by the plasma for creation of radical and ion species, which increases the plasma density and reduces collision broadening of the ion energy distribution to achieve a narrow energy distribution.

Microwave plasma also has other advantages such as lower ion energies with a narrow energy distribution. For instance, microwave plasma may have low ion energy of 1-25 eV, which leads to lower damage when compared to RF plasma. In contrast, standard planar discharge would result in high ion energy of 100 eV with a broader distribution in ion energy, which would lead to higher damage, as the ion energy exceeds the binding energy for most materials of interest. This ultimately inhibits the formation of high quality crystalline thin films through introduction of intrinsic defects. With low ion energy and narrow energy distribution, microwave plasma can help in surface modification and can improve coating properties.

In addition, a lower substrate temperature (e.g., lower than 200° C., for instance at 100° C.) can be achieved, as a result of increased plasma density at lower ion energy with narrow energy distribution. Such a lower temperature allows better microcrystalline growth in kinetically limited conditions. Also, standard planar discharge without magnetron normally requires pressure greater than about 50 mtorr to maintain self-sustained discharge, as plasma becomes unstable at pressure lower than about 50 mtorr. The microwave plasma technology described herein allows the pressure to range from about 10⁻⁶ torr to 1 atmospheric pressure. The processing windows such as temperature and pressure are therefore extended by using a microwave source.

In the past, one drawback associated with microwave source technology in the vacuum coating industry was the difficulty in maintaining homogeneity during scale up from small wafer processing to very large area processing. Microwave reactor designs in accordance with embodiments of the invention can address these problems. Arrays of coaxial plasma linear sources have been developed to deposit substantially uniform coatings of ultra large area (greater than 1 m²) at high deposition rate to form dense and/or thick films (e.g., 5-10 μm thick).

Nonconductive and conductive films have been deposited by utilizing plasma enhanced chemical vapor sources with many types of power sources and system configurations. Most of these sources utilize microwave, HF, or VHF energy to generate excited plasma species. It has been demonstrated in the industry that for a given process condition and system configuration of PECVD, average power into plasma discharge is a major contributing factor to density of radicalized plasma species.

For typical PECVD processes, necessary density of radicalized species must be greater than that required to fully convert all organic materials that include consumption of precursors used in film deposition processes, and loss of these precursors not related to the deposition processes, for example, recombination mechanisms and pumping.

Depending upon the power type, configuration and materials utilized, the required power level can unduly heat the substrate beyond its physical limits, and possibly renders the films and substrate unusable. An advanced pulsing technique has been developed to control the microwave power for generating plasma, and thus to control the plasma density and plasma temperature. This advanced pulsing technique may reduce the thermal load disposed over the substrate, as the average power may remain low. This feature is relevant when the substrate has a low melting point or a low glass transition temperature, such as in the case of a polymer substrate. The advanced pulsing technique allows high power pulsing into plasma with off times in between pulses, which can reduce the need for continuous heating of the substrate. Another aspect of the pulsing technique is significant improvement in plasma efficiency compared to continuous microwave power.

Film properties are achieved by varying process conditions during deposition, including, among others, power levels, pulsing frequency, and duty cycle of the source. The film properties may be controlled by varying density of radical species. The radical density may be controlled primarily by average and peak power levels into the plasma discharge. To achieve required film properties, structure and structural content of the deposited film need to be controlled. For example, the organic content of the film needs to be finely controlled to achieve desired film properties and promote adhesion to certain types of substrates. Embodiments of the present invention focus on methods that directly affect the density of the radical reactive species.

Microwave Coaxial Linear Sources

In a coaxial plasma line source, microwave power is delivered into a vacuum chamber in a transversal electromagnetic (TEM) wave mode. Inside the vacuum chamber, a tube made of a dielectric material, which acts as the atmosphere-vacuum interface can replace the outer conductor of the coaxial line. Since the tube requires heat resistance and low dielectric loss, either quartz or alumina can be used in the construction. Microwave power can pass through the tube and ignite a plasma discharge radically. A surface wave sustained linearly extended discharge is obtained by replacing the metal outer conductor of the coaxial line by an electrically conductive plasma discharge. The microwave power propagation along the plasma line experiences a high attenuation by converting electromagnetic energy into plasma energy.

Typical coating machines for the plasma display industry utilize horizontal coating machines for the deposition of the dielectric layers and the protection layer, because the source type for depositing MgO using electron beam technology is different from the source for planar PECVD of dielectric layers. The microwave coaxial plasma line source allows for both vertical and horizontal configurations. According to embodiments of the present invention, microwave coaxial plasma line source may be arranged in the vertical configuration for depositing dielectric and protection layers coating for plasma display manufacturing. By placing the microwave coaxial plasma line source in the vertical configuration, the substrate can be free of the particles that would otherwise have fallen onto the substrate in the horizontal configuration.

Dielectric Constant and Light Efficiency of Plasma Display

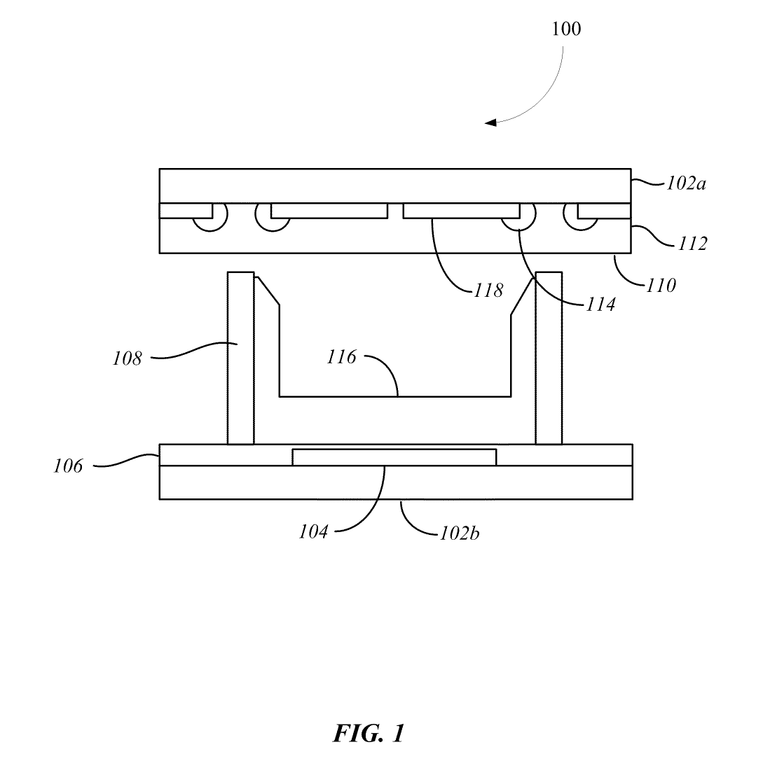

The conventional deposition process normally yields a dielectric constant of 15-16. By using a microwave coaxial plasma line source, carrier gases used for the production of reactive gas phase species, and organo-silicon precursors, a dielectric layer can be deposited to have a typical dielectric constant of 4-5. Microwave plasma generates radicals by dissociating silicon containing precursors, and/or oxygen or nitrogen containing precursors. The radicals form dielectric layers, such as silicon oxide, silicon nitride, or silicon oxynitride, on the substrate. The dielectric layers 112 and 106, shown in FIG. 1, may be 25-30 μm thick.

The dielectric layer 112 can be conformed over the bus bars 114, the discharge sustain electrode or transparent conductive oxide (TCO) coplanar electrode 118, and the top substrate 102a. The dielectric layer 106 is conformed over the address electrode or TCO coplanar electrode 104 and the bottom substrate 102b. The substrates 102a-b may be made of glass.

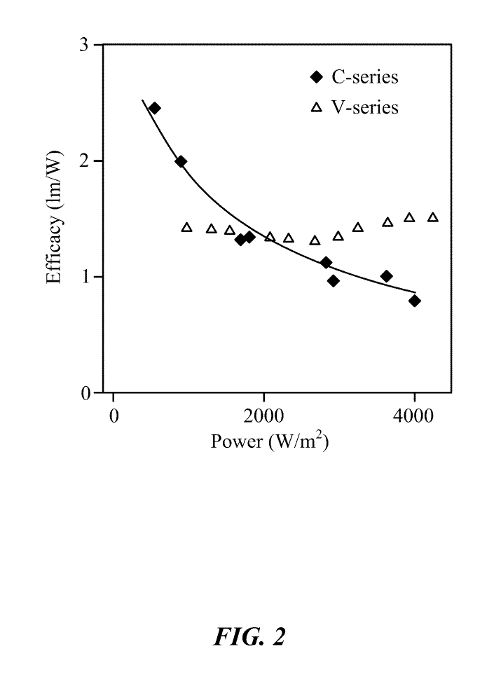

The dielectric constant of 4-5 is significantly lower than 15-16 from the planar PECVD process. Because capacitance is proportional to the dielectric constant, the dielectric layers have lower capacitance. This lower capacitance increases the luminous efficiency of the plasma display. As shown in FIG. 2, lower capacitance yields higher efficiency or more light at lower power levels. However, increasing voltage does not substantially increase light efficiency. As a result of lower dielectric constant of the dielectric layer, the plasma display can yield more light.

Typical coating machines for the plasma display industry utilize horizontal coating machines for the deposition of the dielectric layers and the protection layer, because the source type for depositing MgO using electron beam technology is different from the source for planar PECVD of dielectric layers. The microwave coaxial plasma line source allows for both vertical and horizontal configurations. According to embodiments of the present invention, microwave coaxial plasma line source may be arranged in the vertical configuration for depositing dielectric and protection layers coating for plasma display manufacturing. By placing the microwave coaxial plasma line source in the vertical configuration, the substrate can be free of the particles that would otherwise have fallen onto the substrate in the horizontal configuration.

An alternative to the various techniques of forming the MgO protective layer is utilizing microwave PECVD and a magnesium containing precursor, such as magnesium acetylacetonate and oxygen containing precursor. The microwave PECVD process provides similar film properties, such as adherence and crystallinity, to the sputtering process for the MgO protective layer. The microwave PECVD process also has a benefit of depositing denser films and yielding lower defect densities than the sputtering process. The lower defect densities yield better response time performance.

Microwave Plasma Line Source

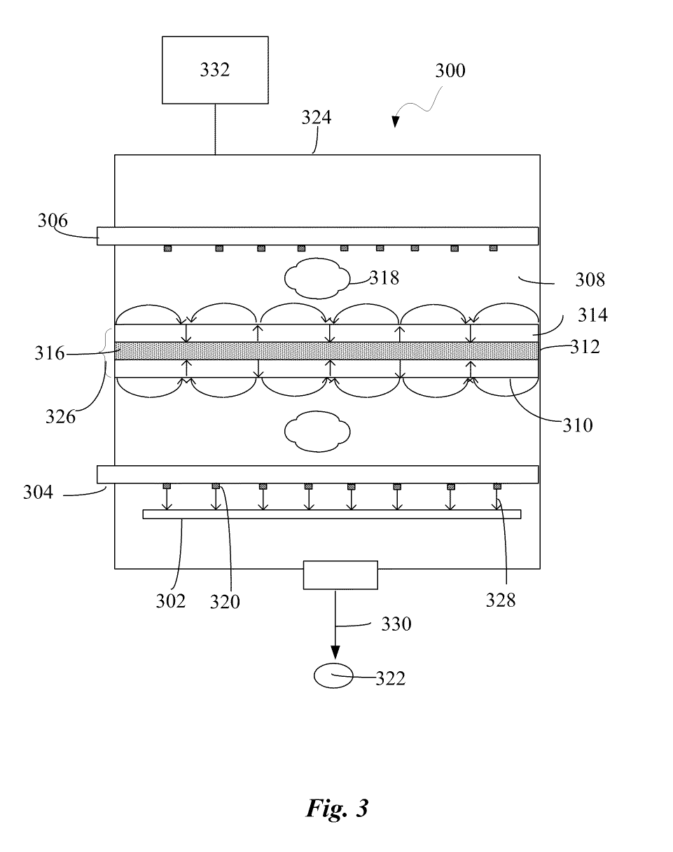

A microwave plasma source has been developed that can be used in various configurations. Such microwave plasma line sources are suitable for deposition of large area on substrates, for example, substrates with an area greater than 1 m², in a static or dynamic coating fashion. FIG. 3 shows a simplified diagram of a coaxial microwave-assisted chemical vapor deposition (CVD) system 300 according to some embodiments of the invention. The major components of the system can include, among other things, a processing chamber 324 that receives precursors from feedstock or precursor gas line 304 and carrier gas line 306, a vacuum system 322, a coaxial microwave line source 326, a substrate 302, and a controller 332.

The coaxial microwave line source 326 can include an antenna 312, a microwave source 316, an outer envelope surrounding the antenna 312, and atmospheric pressure region 314 inside the dielectric layer 310. The microwave source 316 can input microwaves into the antenna 312. The outer envelope can surround the antenna 312 and can be made of dielectric material (e.g., quartz). The outer envelope can serve as a barrier between the vacuum pressure 308 and atmospheric pressure 314 inside the dielectric layer 310. The atmospheric pressure can be used for cooling the antenna 312. Electromagnetic waves can radiate into the chamber 324 through the dielectric layer 310 and plasma 318 may be formed over the surface of the dielectric material such as quartz. In a specific embodiment, the coaxial microwave line source 326 may be about 1 m long. An array of the coaxial microwave line sources 326 may sometimes be used in the processing chamber 324.

The precursor gas line 304 may be located below the coaxial microwave line source 326 and above the substrate 302 which is near the bottom of the processing chamber 324. The carrier gas line 306 may be located above the coaxial microwave line source 326 and near the top of the processing chamber 324. Through the precursor gas line 304 and perforated holes 320, the precursor gases and carrier gases flow into the processing chamber 324. The precursor gases are vented toward the substrate 302 (as indicated by arrows 328), where they may be uniformly distributed radically across the substrate surface, typically in a laminar flow. After deposition is completed, exhaust gases exit the processing chamber 324 by using vacuum pump 322 through exhaust line 330.

The controller 332 controls activities and operating parameters of the deposition system, such as the timing, mixture of gases, chamber pressure, chamber temperature, pulse modulation, microwave power levels, and other parameters of a particular process.

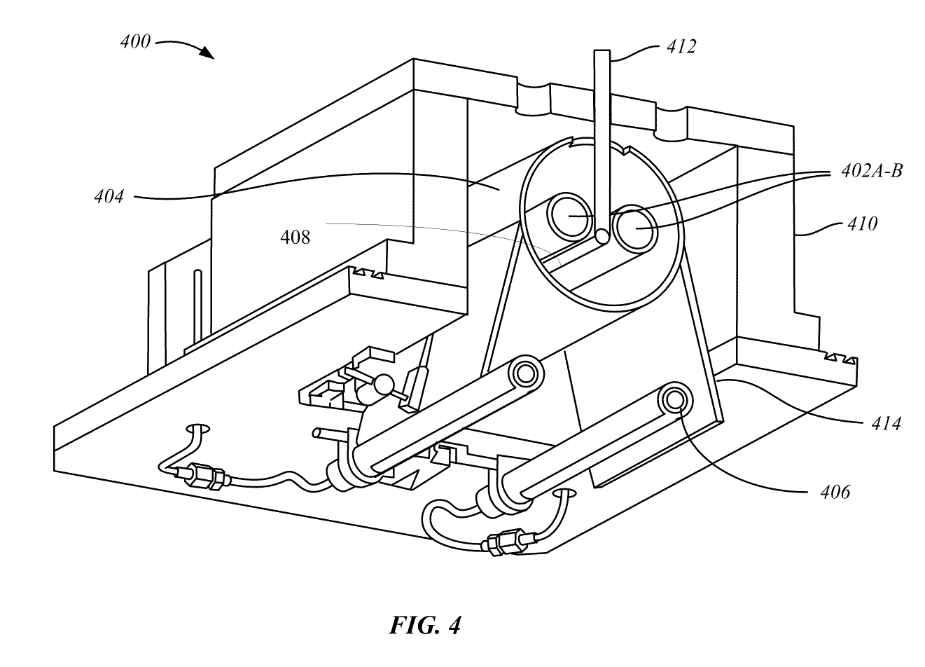

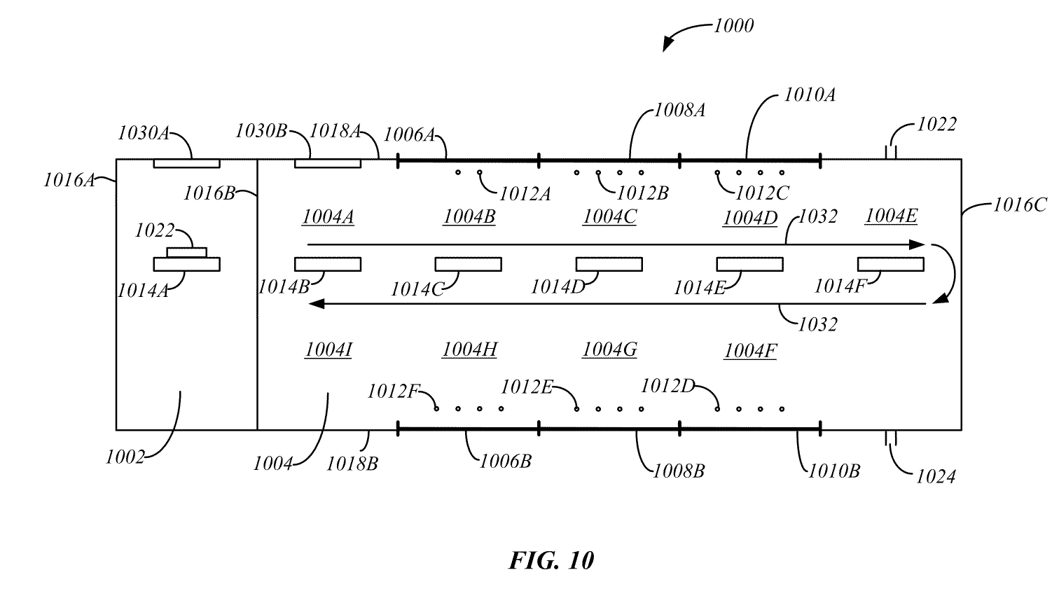

FIG. 4 illustrates one embodiment of a vertical microwave source system 400 according to some embodiments of the invention. The source system 400 can include a frame 410, twin antennas 402A-B, a recombination shield 404 surrounding the twin antennas 402A-B. The source system may also include precursor lines 406 that can be arranged parallel to the twin antenna 402 and/or a carrier gas line 408. The carrier gas line 408 can be positioned between a first antenna 402A and a second antenna 402B and can be parallel to the twin antenna 402. The carrier gas line 408 can be connected to gas inlet 412. The frame 410 may be configured to attach to any portion of a processing chamber. For example, the frame can be attached to any of the door panels 1006A-B and 1008A-B and/or on the sidewalls 1018A-B of the processing chamber shown in FIG. 10. The source system 400 can also include a side shield 414 for helping create laminar flow. The precursor lines 406A-B and/or the antennas 402A-B can be disposed in a vertical arrangement.

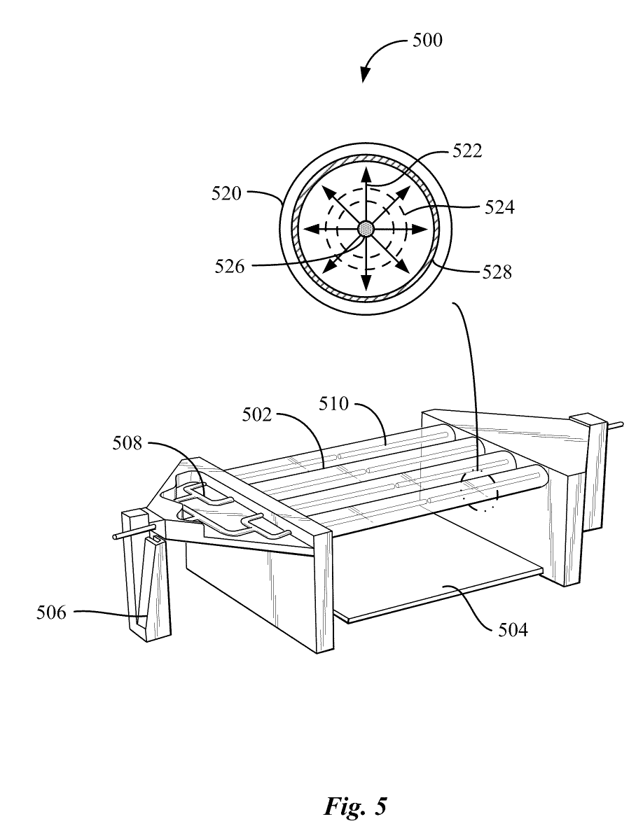

FIG. 5 shows a schematic of a simplified system 500 including a planar coaxial microwave source 502. The planar coaxial microwave source 502 includes 4 coaxial microwave linear sources 510. The simplified system 500 also includes a substrate 504, a Cascade coaxial power provider 508 and an impedance matched rectangular waveguide 506. In the coaxial microwave linear source 510, microwave power is radiated into the chamber in a transversal electromagnetic (TEM) wave mode. A tube replacing the outer conductor of the coaxial line is made of dielectric material such as quartz or alumina having high heat resistance and a low dielectric loss, which acts as the interface between the waveguide having atmospheric pressure and the vacuum chamber.

A cross sectional view of the coaxial microwave linear source 510 illustrates a conductor 526 for radiating microwave at a frequency of 2.45 GHz. The radial lines represent an electric field 522 and the circles represent a magnetic field 524. The microwaves propagates through the air to the dielectric layer 528 and then leak through the dielectric layer 528 to form an outer plasma conductor 520 outside the dielectric layer 528. Such a wave sustained near the coaxial microwave linear source is a surface wave. The microwave propagates along the linear line and goes through a high attenuation by converting electromagnetic energy into plasma energy. Another configuration is without quartz or alumina outside the microwave source (not shown). Such a planar source may be used in FIG. 3 to replace the single coaxial line source.

Deposition Systems

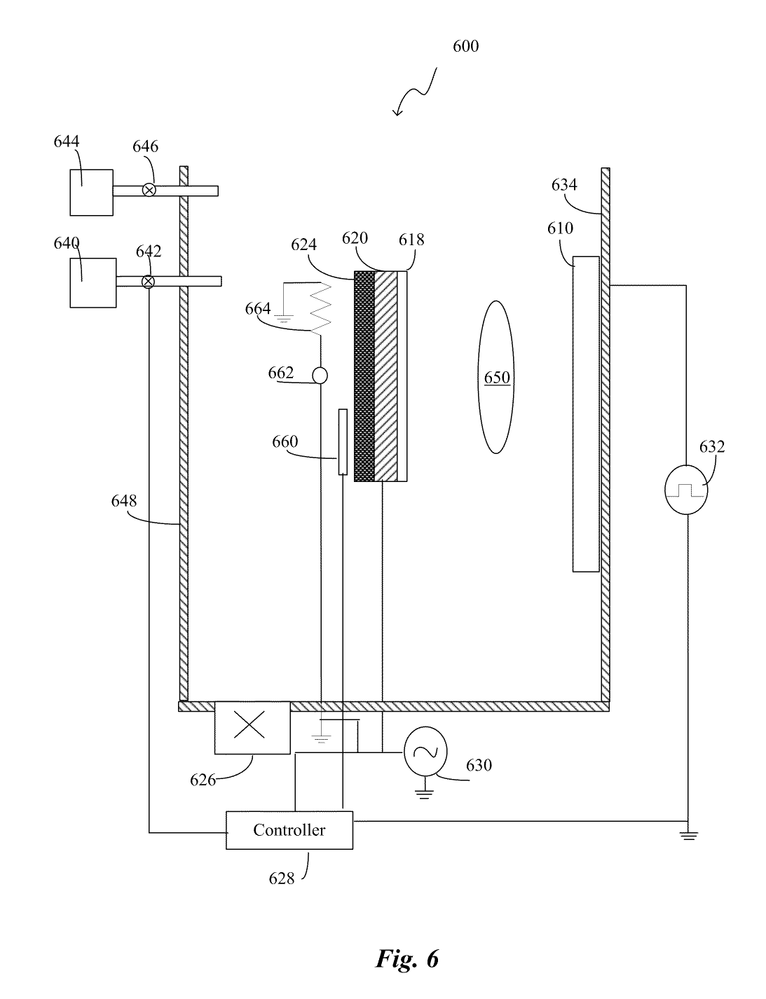

FIG. 6 illustrates an exemplary microwave PECVD system 600 in a vertical arrangement for depositing MgO. The exemplary microwave PECVD system 600 includes a processing chamber 648, an antenna 610 inside the chamber 648 vertically attached to a sidewall 634 of the processing chamber 648. The system 600 also illustrates a substrate 620 on a substrate supporting member 624 in a vertical configuration such that the substrate 620 is parallel to the sidewall 634. The system 600 further includes gas delivery systems 644 and 640 with valves 646 and 642, a vacuum pump system 626, and a controller 628. The substrate 620 may be heated by a heater 664 controlled using a power supply 662. The substrate may also be cooled by using a chiller 660. The substrate supporting member 624 is electrically conductive and may be biased by an RF power 630. A plasma 650 is formed between the microwave antenna 610 and the substrate. Again, the position of the antenna 610 may be adjusted by the controller 628. The antenna 610 is a coaxial microwave plasma source and is subjected to a pulsing power 632 or a continuous power (not shown). The gas delivery systems 644 and 640 provide the essential material sources for forming films 618 on the substrate 620.

The gas delivery systems may introduce magnesium containing precursors and oxygen-containing precursors that may include carrier gases such that a magnesium oxide layer can be deposited. The gas delivery systems may also introduce silicon containing precursors to deposit dielectric layers, such as silicon oxide, silicon nitride, silicon oxynitride on the substrate prior to depositing magnesium oxide. Microwave plasma dissociates the precursors to generate reactive radicals. Then, the reactive radicals form magnesium oxide layers on the substrate that may have the dielectric layers deposited in the case of plasma display application.

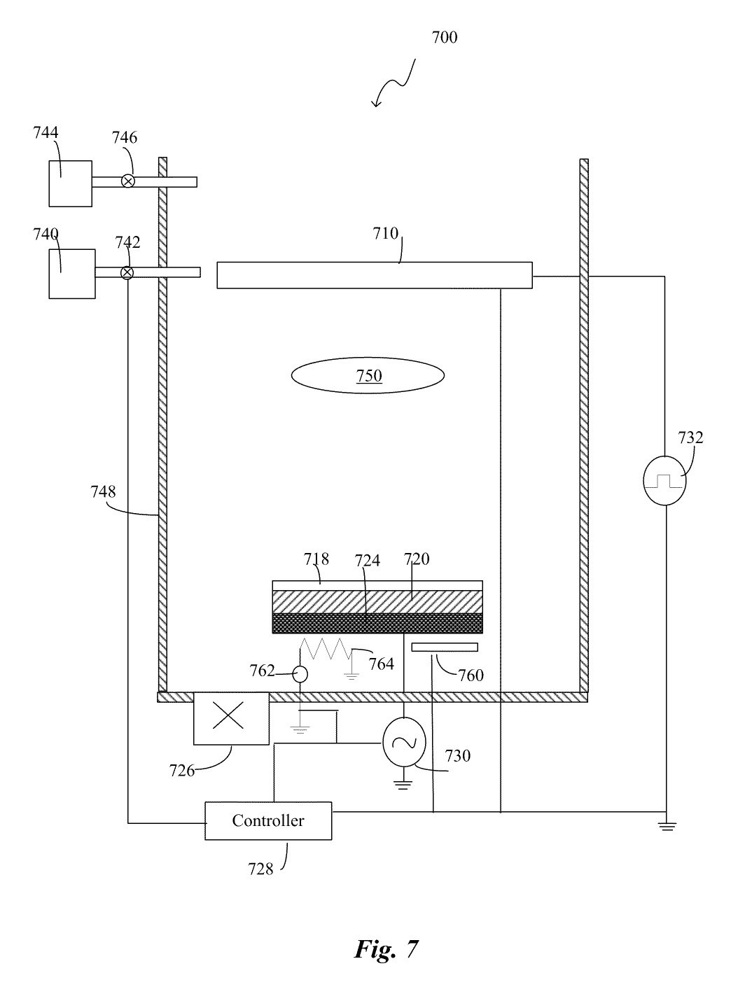

FIG. 7 illustrates an exemplary microwave PECVD system 700 in a horizontal arrangement for depositing MgO. The system 700 includes a processing chamber 748, an antenna 710 positioned horizontally inside the chamber above the substrate 720, a substrate 720 on a substrate supporting member 724 positioned horizontally, gas delivery systems 744 and 740 with valves 746 and 742, a vacuum pump system 726, and a controller 728. The substrate may be heated by a heater 764 that is controlled using a power supply 762. The substrate may also be cooled by using a chiller 760. The substrate supporting member 724 is electrically conductive and may be biased by an RF power 730. A plasma 750 is formed between the microwave antenna 710 and the substrate 720 inside the processing chamber 748. Again, the position of the antenna 710 may be adjusted by the controller 728. The antenna 710 is a coaxial microwave plasma source and is subjected to a pulsing power 732 or a continuous power (not shown). The gas delivery systems 744 and 740 provide the essential material sources for forming films 718 on the substrate 720.

A Sample Process

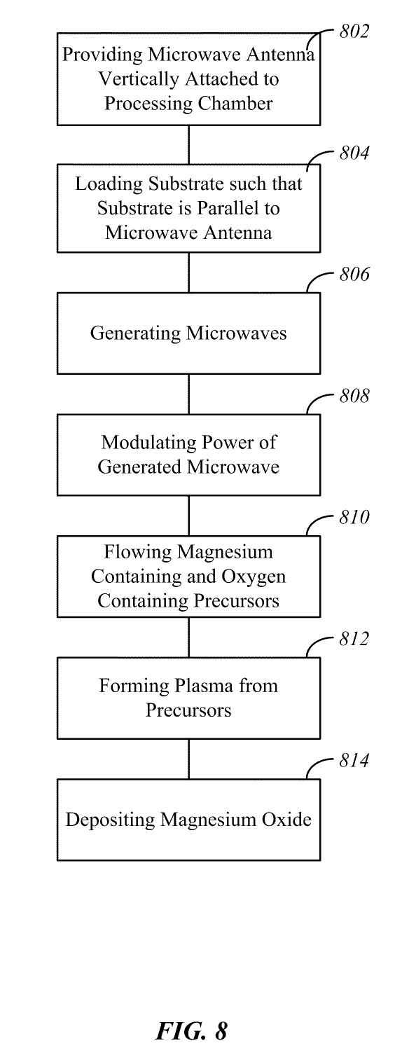

For purposes of illustration, FIG. 8 provides a flow diagram of a process that may be used to deposit a magnesium oxide on a substrate. The process begins with providing a microwave coaxial line source vertically attached to a portion of a sidewall of the processing chamber at block 802. The processing chamber also includes a substrate support member vertically positioned to be parallel to the microwave antenna, as shown in FIG. 6. Next, the substrate is loaded into a processing chamber having one or more of the features discussed above, as indicated at block 804. The process is followed by generating microwaves at block 806 and modulating power of the generated microwaves at block 808.

MgO deposition is initiated by flowing precursor gases to the processing chamber at block 810. For deposition of a magnesium oxide layer, such precursor gases may include a magnesium-containing gas such as magnesium acetylacetonate and an oxygen-containing gas, such as molecular oxygen (O₂), N₂O, NO, NO₂, and/or ozone (O₃). In addition, the precursor gases may comprise a fluent or carrier gas, which may also act as a sputtering agent. The oxidizing precursor may include one or more carrier gas such as helium, argon, nitrogen (N₂), hydrogen (H₂), among other carrier gases. For example, the fluent gas may be provided with a flow of H₂ or with a flow of an inert gas, including a flow of He or even a flow of a heavier inert gas such as Ne, Ar, or Xe. The level of sputtering provided by the different fluent gases is inversely related to their atomic mass (or molecular mass in the case of H₂), with H₂ producing even less sputtering than He. Flows may sometimes be provided of multiple gases, such as by providing both a flow of H₂ and a flow of He, which mix in the processing chamber. Alternatively, multiple gases may sometimes be used to provide the fluent gas, such as when a flow of H₂/He is provided in to the process chamber. It is also possible to provide separate flows of higher-mass gases, or to include higher-mass gases in the premixture.

As indicated at block 812, a plasma is formed from the precursor gases. Plasma conditions (e.g., microwave power, microwave frequencies, pressure, temperature, carrier gas partial pressures, etc.) may vary to meet the need of a particular application. In some embodiments, the plasma may be a high-density plasma having an ion density that exceeds 10¹² ions/cm³. Also, in some instances the deposition characteristics may be affected by applying an electrical bias to the substrate. Application of such a bias causes the ionic species of the plasma to be attracted to the substrate, sometimes resulting in increased sputtering. The environment within the processing chamber may also be regulated in other ways in some embodiments, such as by controlling the pressure within the processing chamber, controlling the flow rates of the precursor gases and where they enter the processing chamber, controlling the power used in generating the plasma, controlling the power used in biasing the substrate, and the like. Under the conditions defined for processing a particular substrate, material is thus deposited over the substrate as indicated at block 814.

In some instances, prior to the deposition process of MgO, a dielectric layer may be deposited over the substrate as in the plasma display. One benefit to deposit the MgO in a vertical configuration is to deposit the MgO after depositing the dielectric layer in an integrated deposition system. Such integrated deposition system and deposition process is described in U.S. patent application Ser. No. ______, entitled “Dynamic Vertical Deposition of Plasma Display Layers”, by Michael Stowell, the entire content of which is incorporated herein by reference for all purposes.

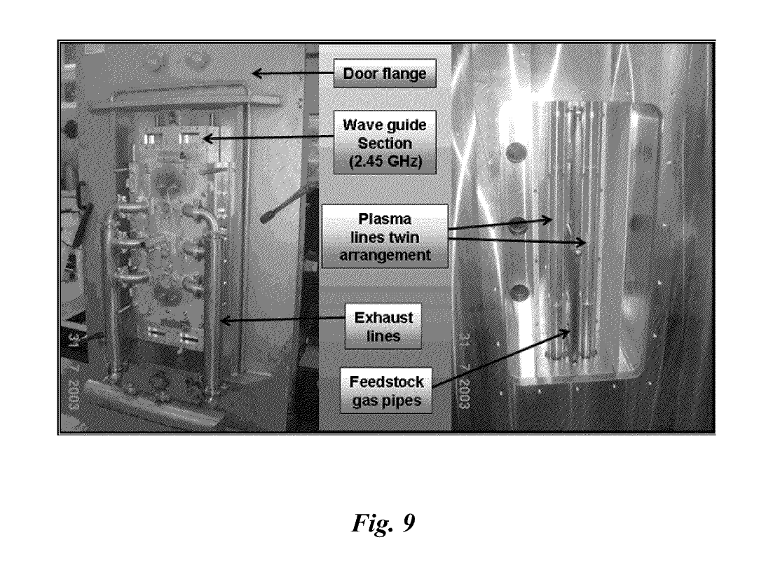

FIG. 9 shows a photograph of an example of a vertical microwave coaxial plasma line source in early development stage. Such a system has been successfully used for deposition of dielectric layer in a vertical configuration. This example system is about 20 feet long, 4 feet in depth and 7 feet tall.

Dynamic Vertical Deposition System

A deposition system may be fabricated by utilizing a plurality of microwave coaxial plasma line sources, where each line source is arranged in a vertical configuration to produce coatings in a dynamic fashion. A vertical configuration of microwave coaxial plasma source can allow a magnesium oxide layer to be deposited directly after deposition of a dielectric layer. A combined deposition processes in a single chamber can remove the necessity for venting after depositing the dielectric layer. The venting is needed for further vacuum coating by utilizing a traditional electron beam evaporation system for depositing the magnesium oxide over the dielectric layer. The deposition system also removes the typical by-products of traditional processes through the use of the microwave coaxial plasma source and thus no drying ovens are needed as required for the traditional processes. The combined deposition process can remove a process cycle to bake out the dielectric layer and the magnesium oxide layer to remove VOC of the typical by-products of the traditional processes. As a result, in comparison with traditional plasma display manufacturing, the deposition system can occupy 80% of the floor space, can use about 40% or less of the power plant, and shortens the product manufacturing cycle from about 8-12 hours to possibly as low as 10 minutes or less.

According to embodiments of the present invention, FIG. 10 illustrates a top view of an exemplary dynamic vertical in-line system 1000 for deposition of plasma display dielectric and protection layers. The vertical in-line system 1000 includes a preheating chamber 1002 also having sidewalls 1016A, 1016B, 1018A, and 1018B, and a deposition chamber 1004 that is separated from the preheating chamber 1002 by the sidewall 1016B and having sidewalls 1018A, 1018B, and 1016C. The preheating chamber 1002 and the deposition chamber 1004 share common sidewalls 1018A and 1018B. The sidewalls 1018A and 1018B may be parallel to each other, and/or can be perpendicular to the sidewalls 1016A, 1016B and 1016C.

Inside the preheating chamber 1002, a substrate supporting member 1014A can be positioned vertically and/or positioned parallel to the sidewalls 1018A or 1018B. The substrate supporting member can be detachably coupled with the substrate and can keep the substrate in a vertical position throughout processing. A set of heaters 1030A, such as Infrared (IR) radiators, may be attached to the sidewall 1018A for preheating a substrate on the substrate supporting member 1014A in the preheating chamber 1002.

The deposition chamber 1004 can include a set of sub-chambers 1004A-I with or without sidewalls in between neighboring sub-chambers. In the figure, sub-chambers 1004A-304E share a common sidewall 1018A, while the sub-chambers 1004E-304I share the opposite sidewall 1018B. In some embodiments, there are no sidewalls parallel to the sidewalls 1016A-C between the neighboring sub-chambers, such as 1004A and 1004B, 1004B and 1004C. In some embodiments, there are also no walls parallel to the sidewalls 1018A-B between the neighboring sub-chambers, such as 1004B and 1004H, 1004C and 1004G. In the deposition chamber 1004, there may be a plurality of carriers or substrate supporting members 1014A-314F for vertically holding a substrate 1022 to be parallel to the sidewalls 1018A and 1018B. The substrate supporting members 1014A-314E can act to separate the sub-chambers 1004A-304D from the sub-chambers 1004F-304I along horizontal direction as pointed by arrow 1032.

In some embodiments, the sub-chambers 1004B-D have door panels 1006A, 1008A, and 1010A attached to the sidewall 1018A, respectively. The sub-chambers 1004F-H have door panel 1010B, 1008B and 1006B attached to the sidewall 1018B, respectively. According to some embodiments of the invention, a plurality of microwave plasma sources 1012A-312F can be attached to the door panels 1006A, 1008A, 1010A, 1010B, 1008B, 1006B, respectively. A first microwave plasma source 1012A may include a single twin-line source (illustrated in FIG. 4 above). Second, third, fourth, fifth, and sixth microwave plasma sources 1012B-312F may include two or more twin-line sources to increase plasma density.

The deposition may also include a sub-chamber for heating the substrate to a desired temperature. Another set of heaters 1030B, such as IR radiators, may be attached to the sidewall 1018A for further heating the substrate on the substrate supporting member 1014A in the sub-chamber 1004A of the deposition chamber 1004.

The substrate supporting member 1014F in the sub-chamber 1004E can be configured to rotate the substrate 1022 by 180 degrees around a vertical axis such that the substrate 1022 can face toward either the sidewall 1018A or the sidewall 1018B. The substrate 1022 can be dynamically transported from the preheating chamber 1002 to the deposition chamber 1004, and from the first sub-chamber 1004A to the second sub-chamber 1004B and then to the third sub-chamber 1004C, the fourth sub-chamber 1004D, and so on until till the eighth sub-chamber 1004H. During transportation the substrate 1022 can be supported by the substrate supporting members in each chamber or sub-chamber.

In sub-chambers 1004A-F, various steps can be performed, for example, preheating, pretreatment, deposition of dielectric layer, rotation of the substrate, and/or deposition of material such as magnesium oxide. The deposition can be performed in a dynamic mode, where the substrate is configured to be transported from one sub-chamber to another sub-chamber and go through various process steps. In some alternative embodiments, the substrate may be configured to transfer along with a substrate supporting member or carrier from one sub-chamber to another sub-chamber.

In some embodiments, there can be more sub-chambers for deposition of dielectric layer than for deposition of magnesium oxide. Such a configuration would allow to deposit thicker dielectric layer than the protection layer. For example, for a plasma display, a typical dielectric layer may have a thickness of approximately 23-30 μm, while a typical protection layer such as MgO may have a thickness of approximately 2 μm.

The system 1000 can also include a one or more inlets 1022 for flowing precursor gases on one or both of the sidewalls, such as 1018A or 1018B. The system 1000 can include at least one gas exhaust outlet 1024. Valves for controlling inlets 1022 and/or outlet 1024 can also be included.

Each of the carriers or substrate supporting members 1014C-314E can be configured to be movable toward the sidewalls such that adjustment in the distance between the plasma sources 1012A-F and the substrate 1022 on any of the substrate supporting members 1014C-314E can be made. In a particular embodiment, the distance between the plasma sources and the substrate may be 15 cm for depositing dielectric layer, while the distance between the plasma sources and the substrate may be between 5 cm and 15 cm for depositing MgO. In some embodiments, the carriers or substrate supporting members 1014C-314E can automatically be placed at an ideal position from plasma or heat sources.

While FIG. 10 has been shown with nine sub-chambers, similar machines can be developed with any number of chambers. For example, single vertical deposition chambers can be used where a substrate is exposed to vertical plasma line source for deposition. Various other combinations of sub-chambers (e.g., deposition, pre-treating, annealing, heating, etc. sub-chambers) can be used in any combination.

Benefits of such a deposition system can include significantly reduced floor space because of the vertical configuration to allow deposition from two sides by rotating the substrate 1022 on the substrate supporting member 1014F. The benefits can also include that the substrate is free from particles or contamination as a result of vertical configuration. Vertical deposition process can also provide a uniform deposition profile. And the bowing and/or cracking of dielectric layers can be mitigated using a vertical deposition system.

In some embodiments of the invention, a dielectric layer and a protection layer can be deposited within the same deposition chamber using vertical deposition techniques described herein. Various other deposition and our treatment techniques can also be performed on a substrate in a vertical configuration.

According to an alternative embodiment of the present invention, the deposition chamber may increase the number of microwave plasma line sources in order to shorten the deposition time. For example, in a specific embodiment, there are 4 twin line sources on each of the door panels 1008A-B, 1010A-B, 1006B, the door panels may need to be enlarged. The deposition time for achieving the same thickness of film may be reduced from 10 minutes to 5-7 minutes when 4 twin line sources are used. Although the number of sources increases by a factor of 2, it does not necessarily reduce the deposition time linearly. One of ordinary skill in the art would recognize many variations, modifications, and alternatives.

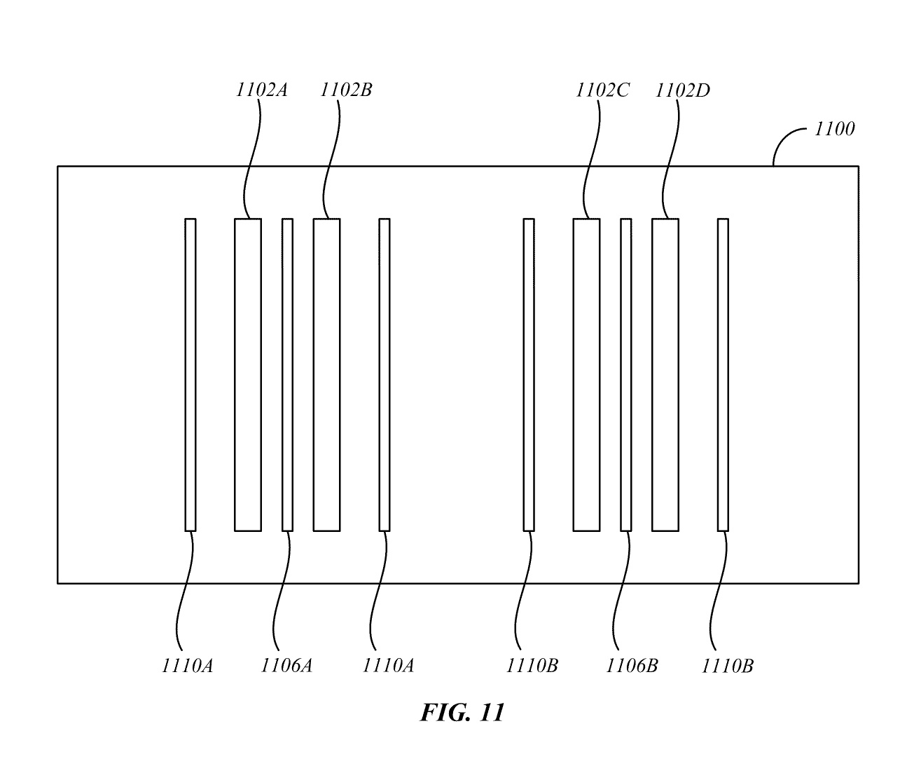

FIG. 11 illustrates a side view of door panel 1100 with a plasma source attached. For example, door panels 1008A-B and/or 1006B can implement door panel 1100. A first twin antenna 1102A-B can be disposed on the left and a second twin antenna source 1102C-D can be disposed on the right. A carrier gas line 1106A can be located inside the first twin antenna source 1102A-B, specifically, between the antenna sources 1102A and 1102B, and another carrier gas line 1106B can be located inside the second twin antenna source 1102C-D, i.e. between the two antenna 1102C and 1102D. Additionally, precursor pipe lines can be located outside recombination shields 1110A-B that surround the first and the second twin antenna sources 1102A-B and 1102C-D, respectively. In some embodiments, fewer microwave twin antennas or twin-line sources can be used for pretreatment of substrate than for deposition, because lower plasma density is required in the pretreatment than deposition.

Although embodiments of the invention illustrate vertical deposition system with the antenna sources vertically attached to the processing chamber, alternative embodiments may include horizontal configurations of the antenna sources above a horizontally positioned substrate for a horizontal deposition. In systems with such horizontal configurations, depositions of a magnesium oxide layer over a dielectric layer may be performed in a single integrated system using the antenna sources.

Exemplary Microwave Plasma-Assisted CVD Process

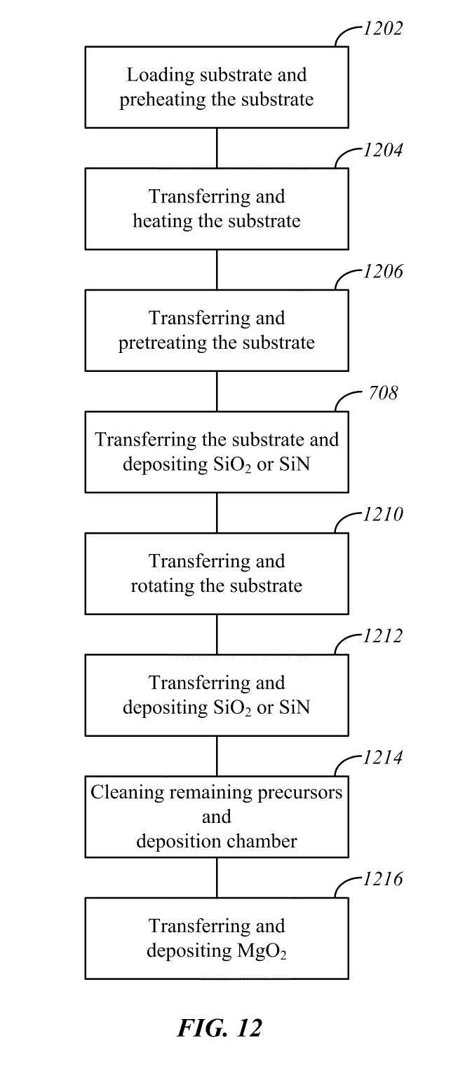

FIG. 12 illustrates a flow diagram that can be used in a dynamic vertical deposition system, such as the system shown in FIG. 10. In some embodiments, the system can include at least a preheating chamber and a deposition chamber. The deposition chamber can include a first sub-chamber for preheating the substrate to a second temperature. The deposition chamber can include a second sub-chamber for pretreatment of the substrate surface. The deposition chamber can include a third and fourth sub-chambers for depositing dielectric layer. The deposition chamber can also include a fifth sub-chamber for rotating the substrate with a carrier, and a sixth and seventh sub-chamber for depositing more dielectric material. The deposition chamber can include an eighth sub-chamber for depositing magnesium oxide.

The process starts with loading a substrate to the preheating chamber at block 1202 and preheating the substrate to a first temperature. The process can also include transferring the substrate to the first sub-chamber and heating the substrate to a second temperature at block 1204. The process further includes transferring the substrate to the second sub-chamber and pretreating the substrate at block 1206 in the second sub-chamber. For example, the pre-treatment can include plasma cleaning, plasma etching to generate surface morphology, and/or surface activation for promoting better adhesion.

Following block 1206, the process can transfer the pretreated substrate to the third sub-chamber at block 1208. Within the third subchamger a dielectric layer can be deposited. The dielectric layer, such as silicon oxide is deposited by introducing precursors for forming a dielectric oxide film. The oxide film precursors may include a reactive species precursor such as radical atomic oxygen, as well as other oxidizing precursors such as molecular oxygen (O₂), ozone (O₃), water vapor, hydrogen peroxide (H₂O₂), and nitrogen oxides (e.g., N₂O, NO₂, etc.) among other oxidizing precursors. The oxide film precursors can also include silicon-containing precursors, such as organo-silane compounds including TEOS, OMCTS, HMDS, TMCTR, TMCTS, OMTS, TMS, and HMDSO, among others. The silicon-containing precursors may also include silicon compounds that don't have carbon, such as silane (SiH₄). If the film is a dielectric silicon nitride or silicon oxynitride, then nitrogen-containing precursors may also be used, such as ammonia. All of these deposition precursors may be transported by carrier gases, which may include helium, argon, nitrogen (N₂), and hydrogen (H₂), among other gases.

The substrate may be transferred to the fourth sub-chamber for further dielectric material deposition using other microwave sources. The process can continue by transferring the substrate along with the carrier to the fifth sub-chamber and rotating the substrate 180 degrees at block 1210 such that the substrate faces toward the opposite sidewall of the deposition chamber. The process further includes transferring the substrate to the sixth and seventh sub-chamber and further deposition of dielectric material(s) at block 1212.

After depositing the dielectric layer, the process may continue by removing any remaining precursors and products at block 1214. The deposition chamber may also be cleaned by introducing cleaning gases. For example, when nitrofluorinated etching gases such as NF₃ or carbofluorinated etching gases such as C₂F₆, C₃F₈ or CF₄ are introduced into the chamber, the unwanted materials deposited on components of the chamber may be removed by plasma etching or cleaning.

The process can then be followed by transferring the substrate to the eighth sub-chamber. Magnesium containing precursors can be introduced during a magnesium oxide deposition at block 1216. For deposition of a magnesium oxide layer, the precursors may include magnesium acetylacetonate and an oxygen-containing gas, such as molecular oxygen (O₂), N₂O, NO, NO₂, and/or ozone (O₃). In addition, the precursor gases may comprise a fluent or carrier gas, which may also act as a sputtering agent. The oxidizing precursor may include one or more carrier gas such as helium, argon, nitrogen (N₂), hydrogen (H₂), among other carrier gases. For example, the fluent gas may be provided with a flow of H₂ or with a flow of an inert gas, including a flow of He or even a flow of a heavier inert gas such as Ne, Ar, or Xe. The level of sputtering provided by the different fluent gases is inversely related to their atomic mass (or molecular mass in the case of H₂), with H₂ producing even less sputtering than He. Flows may sometimes be provided of multiple gases, such as by providing both a flow of H₂ and a flow of He, which mix in the processing chamber. Alternatively, multiple gases may sometimes be used to provide the fluent gas, such as when a flow of H₂/He is provided in to the process chamber. It is also possible to provide separate flows of higher-mass gases, or to include higher-mass gases in the premixture.

In some embodiments, the substrate may be transferred along with a substrate supporting member or carrier from one sub-chamber to another sub-chamber.

Such a combined process of depositing MgO and depositing dielectric layer in a single dynamic vertical deposition system may reduce the processing time to approximately 10 minutes or less. This is significantly shorter than a normal processing time of 10-12 hours for conventional depositing MgO by using electron beam evaporation deposition after depositing the dielectric layer.

There are many benefits to using the vertical configuration described in the various embodiments. These benefits can include reduction of the particle density, and toxic by-products, compared to the traditional equipment. The single deposition system may reduce approximately 80% of the floor space of the traditional plant and 60% or more of the manufacturing power of the traditional process. The reason for this is that the traditional process requires drying oven for baking out the VOC from the binders which are not present in the dynamic coating process for depositing the dual layers using the single deposition chamber. The drying ovens need significantly large floor space and large amount of power consumption. The baking process also takes long time, such as hours. Furthermore, deposition time can be significantly reduced.

For consumers, the operation power of the plasma display panel fabricated with a single deposition chamber is reduced to 50% of a typical plasma display panel, as a result of lower dielectric constant of 4-5 produced for the dielectric layers. Moreover, electrodes in the plasma display may be thinner, which may result additional cost reduction in manufacturing, such as low usage of conductive materials and shorter process cycle.

According to embodiments of the present invention, the system and process may have potential applications, including, among others but not limited to, plasma display dielectric coating and protection layer coating, dynamic coatings and etching for solar panels, semiconductor industry, and functional coatings industries.

Thus, having described several embodiments, it will be recognized by those of skill in the art that various modifications, alternative constructions, and equivalents may be used without departing from the spirit of the invention. Accordingly, the above description should not be taken as limiting the scope of the invention, which is defined in the following claims.

What is claimed is:

1. A microwave plasma deposition system comprising:
a processing chamber;
a substrate supporting member coupled with a substrate and configured to support the substrate in a vertical position within the processing chamber;
a first microwave plasma line source disposed within the processing chamber and arranged in a vertical configuration, the first microwave plasma line source configured to deposit a dielectric layer on the substrate; and
a second microwave plasma line source disposed within the processing chamber and arranged in a vertical configuration, the second microwave plasma line source configured to deposit a protection layer on the substrate.

2. The microwave plasma deposition system of claim 1, wherein the first microwave plasma line source is located within a first sub-chamber of the processing chamber, and the second microwave plasma line source is located within a second sub-chamber of the processing chamber.

3. The microwave plasma deposition system of claim 1 further comprising a pretreatment chamber.

4. The microwave plasma deposition system of claim 1 further comprising heating elements within the processing chamber.

5. The microwave plasma deposition system of claim 1, wherein the substrate supporting member is configured to move the substrate between the first microwave plasma line source and the second microwave plasma line source.

6. A deposition system comprising:
a processing chamber having a first, second, third and fourth sub-chambers, the first and second sub-chambers having a first and a second microwave plasma line sources vertically coupled to a first sidewall of the processing chamber, the third and fourth sub-chambers having a third and a fourth microwave plasma line sources vertically coupled to a second sidewall of the processing chamber;
at least one substrate supporting member for supporting a substrate in a vertical configuration within the processing chamber, wherein the substrate supporting member is positioned between the first sidewall and the second sidewall, wherein the substrate supporting member is configured to rotate the substrate; and
a plurality of precursor lines coupled into the processing chamber.

7. The deposition system of claim 6, further comprising a preheating chamber for heating the substrate, wherein the preheating chamber is separated from the processing chamber by a third sidewall, wherein the third sidewall is substantially perpendicular to the first sidewall and the second sidewall.

8. The deposition system of claim 6, the first, second, third and fourth microwave plasma line sources are vertically attached respectively to a first, second, third and fourth door panels, wherein the first and second door panels are movable portions of the first sidewall and the third and fourth door panels are movable portions of the second sidewall.

9. The deposition system of claim 6, wherein the first microwave plasma line source comprises a twin coaxial line source.

10. The deposition system of claim 6, the substrate is configured to be transported from the third sub-chamber to the fourth sub-chamber along a second direction parallel to the first sidewall and the second sidewall, wherein the second direction is opposite to the first direction.

11. A deposition method comprising:
loading a substrate into a substrate supporting member within a processing chamber, wherein the substrate supporting member is configured to support the substrate in a vertical configuration such that the substrate is substantially parallel to the sidewall;
generating microwaves with a microwave antenna that is disposed vertically within the processing chamber;
modulating a power of the generated microwaves; and
flowing a first precursor and an oxygen-containing precursor into the processing chamber, wherein the first precursor and the oxygen-containing precursor form a first plasma inside the processing chamber in conjunction with the microwaves generated within the processing chamber, and wherein a first layer is formed on the substrate.

12. The method of claim 11 wherein the first precursor comprises magnesium.

13. The method of claim 11 further comprising:
flowing a second precursor and an oxygen-containing precursor into the processing chamber; wherein the second precursor and the oxygen-containing precursor form a second plasma inside the processing chamber in conjunction with the microwaves generated within the processing chamber, and wherein a second layer is formed on the substrate.

14. The method of claim 13, wherein the second precursor comprises silicon.

15. The method of claim 11, wherein the first precursor comprises magnesium acetylacetonate.

16. The method of claim 11, wherein the oxygen containing precursor is selected from the group consisting of molecular oxygen (O₂), ozone (O₃), NO, N₂O, and NO₂.

17. A microwave deposition system comprising:
a processing chamber;
a microwave coaxial line source disposed vertically within the chamber and configured to radiate microwaves;
a substrate supporting member disposed within the processing chamber and configured to hold a substrate vertically such that the substrate is substantially parallel to the sidewall; and
a gas supply system for flowing gases into the processing chamber,
wherein the gas supply system is configured to flow gases into the processing chamber that create a plasma in conjunction with the microwave coaxial line source and deposit a layer on a substrate held by the substrate supporting member.

18. The microwave deposition system of claim 17, wherein the microwave coaxial line source comprises a microwave coaxial twin-line source.

19. The microwave deposition system of claim 17, wherein the microwave coaxial line source comprises a planar source having an array of substantially parallel microwave coaxial line sources.

20. The microwave deposition system of claim 17, wherein the substrate is movable relative to the microwave line source.
